(19) United States
(12) Patent Application Publication
(10) Pub. No.: US 2014/0242792 A1
(43) Pub. Date: Aug. 28, 2014

(54) Method for Forming Semiconductor Device

(71) Applicant: SHANGHAI HUAHONG GRACE SEMICONDUCTOR MANUFACTURING CORPORATION, SHANGHAI (CN)

(72) Inventors: Zhangli LIU, Shanghai (CN); Ernest LI, Shanghai (CN)

(73) Assignee: SHANGHAI HUAHONG GRACE SEMICONDUCTOR MANUFACTURING CORPORATION, SHANGHAI (CN)

(21) Appl. No.: 14/140,738

(22) Filed: Dec. 26, 2013

(30) Foreign Application Priority Data
Feb. 25, 2013 (CN) 201310058916.8

(51) Int. Cl. H01L 21/768

(52) U.S. Cl. CPC H01L 21/7682; H01L 21/76832
USPC 438/624

(57) ABSTRACT

A method for forming a semiconductor device is provided, which may include: providing an interlayer dielectric layer, a metal layer formed on the interlayer dielectric layer, an etch stop layer formed on the metal layer, and a first opening extending through the etch stop layer and the metal layer, wherein the interlayer dielectric layer is exposed from the first opening; forming a protecting layer on the sidewall of the first opening to cover the metal layer; after forming the protecting layer, forming a second opening by etching a portion of the interlayer dielectric layer; and forming an isolating layer by filling up the second opening, wherein the isolating layer includes an air gap. The semiconductor device is more stable in performance.

### CROSS REFERRENCE TO RELATED APPLICATIONS

The present application claims priority to Chinese patent application No. 201310058916.8, filed on Feb. 25, 2013, and entitled “Method for Forming Semiconductor Device”, the entire disclosure of which is incorporated herein by reference.

### TECHNICAL FIELD

The present disclosure generally relates to semiconductor manufacturing technology, and more particularly, to a method for forming a semiconductor device.

### BACKGROUND

With the development of semiconductor integrated circuit technology, the distance between metal wires tends to decrease with the continuous scaling down of a semiconductor device and an interconnecting structure, which causes an isolating layer between the metal wires becomes much thinner, resulting in a crosstalk effect between the metal wires. Nowadays, the crosstalk effect may be reduced effectively by decreasing a dielectric constant of the isolating layer. Further, a low-K (dielectric constant) dielectric layer can effectively reduce RC delay and parasitic capacitance between the metal wires. Accordingly, a low-K dielectric material and an ultra low-K dielectric material become more and more widely used in the isolating layer in interconnecting process.

Air is a substance with a lower dielectric constant (k=1.0). Therefore, to reduce the dielectric constant, an air gap or porosity may be introduced into an isolating layer for forming a low-K or ultra low-K isolating layer, so as to reduce a crosstalk effect between the metal wires.

A conventional method for forming a semiconductor device may include the following processes.

Referring to FIG. 1, an interlayer dielectric layer 100, a metal film 101 formed on the interlayer dielectric layer 100, a TiN film 103 formed on the metal film 101, and a photoresist layer 105 formed on the TiN film 103 are provided. The interlayer dielectric layer 100 includes a dielectric material. The photoresist layer 105 has an opening 107 which exposes a portion of the TiN film 103.

Referring to FIG. 2, the TiN film 103 and the metal film 101 are etched through the opening 107 by using the photoresist layer 105 as a mask, so as to obtain a metal layer 101a on the interlayer dielectric layer 100, a TiN layer 103a, and a groove 109 extending through the metal layer 101a and the TiN layer 103a. Then the photoresist layer 105 is removed.

Referring to FIG. 3, a dielectric material is filled in the groove 109 (shown in FIG. 2), so that an isolating layer 111 covering the TiN layer 103a and filling up the groove 109 is formed. An air gap 113 is formed in the isolating layer 111 inside the groove 109, so as to reduce the K value of the isolating layer 111.

However, the semiconductor device formed with the conventional method has an unstable performance.

More information about a method for forming a semiconductor device may refer to US patent application No. US20080038518A1.

### SUMMARY

Embodiments of the present disclosure provide a method for forming a semiconductor device, which makes the semiconductor device more stable in performance.

In one embodiment, a method for forming a semiconductor device is provided, which may include: providing an interlayer dielectric layer, a metal layer formed on the interlayer dielectric layer, an etch stop layer formed on the metal layer, and a first opening extending through the etch stop layer and the metal layer, wherein the interlayer dielectric layer is exposed from the first opening; forming a protecting layer on a sidewall of the first opening to cover the metal layer; after forming the protecting layer, forming a second opening by etching a portion of the interlayer dielectric layer; and forming an isolating layer by filling up the second opening, wherein the isolating layer includes an air gap.

In some embodiments, the protecting layer may include silicon oxide, silicon nitride or silicon oxynitride.

In some embodiments, the protecting layer may be formed by oxidation of tetraethoxysilane (TEOS).

In some embodiments, the protecting layer may have a thickness ranging from about 100 Å to about 500 Å.

In some embodiments, the second opening may have a depth-to-width ratio greater than 1.2.

In some embodiments, the second opening may be about 2000 Å to about 3000 Å deeper than the first opening.

In some embodiments, the first opening has a depth-to-width ratio equal to or greater than 1:1, and a width ranging from about 4000 Å to about 8000 Å, and a depth ranging from about 4000 Å to about 10000 Å.

In some embodiments, the isolating layer may include silicon oxide.

In some embodiments, the etch stop layer may include silicon nitride or titanium nitride.

In some embodiments, the etch stop layer may have a single-layer structure or a multi-layer stack structure.

Compared with the prior art, this disclosure has the following advantages:

Because the protecting layer is formed on the sidewall of the first opening to cover the metal layer, the metal layer would not be damaged no matter when the interlayer dielectric layer is etched to form the second opening. Further, because the second opening is deeper than the first opening, the air gap is formed more close to the bottom of the metal layer, such that the K value of the isolating layer between adjacent metal layers is further reduced, which thereby effectively alleviates a crosstalk effect between the adjacent metal layers, and improves the stability of the semiconductor device's performance.

### BRIEF DESCRIPTION OF THE DRAWINGS

FIG. 1 to FIG. 3 schematically illustrate cross-sectional views of intermediate structures of a conventional method for forming a semiconductor device;

FIG. 4 schematically illustrates a flow chart of a method for forming a semiconductor device according to one embodiment of the present disclosure; and

FIG. 5 to FIG. 10 schematically illustrate cross-sectional views of intermediate structures of a method for forming a semiconductor device according to one embodiment of the present disclosure.

### DETAILED DESCRIPTION

As described above, the conventional semiconductor device has an unstable performance.

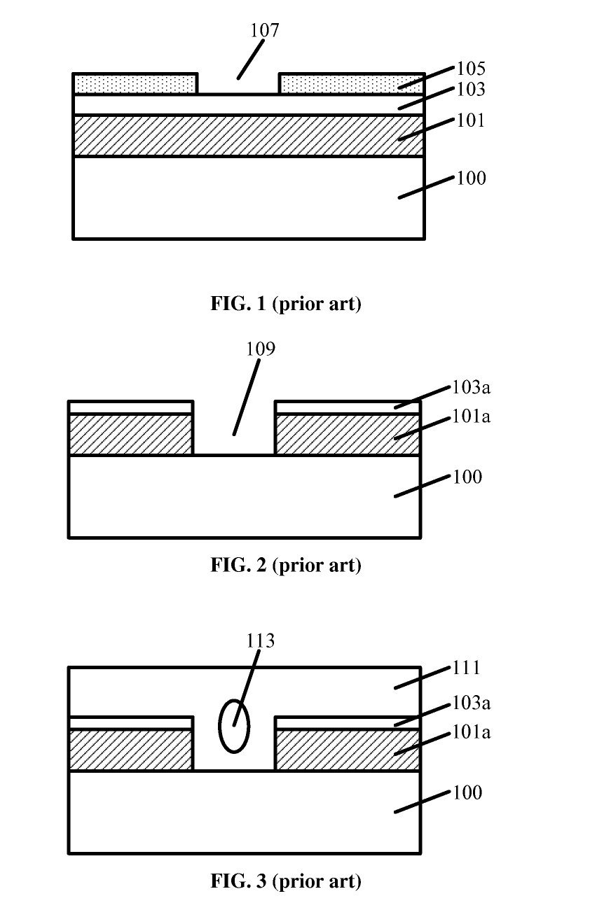

It is found that the reason for the unstable performance of the conventional semiconductor device is: still referring to FIG. 1 to FIG. 3, although the air gap 113 is formed in the isolating layer 111 between the adjacent metal layers 101a, the air gap 113 locates near to the top of the metal layer 101a. There is no air gap formed in a portion of the isolating layer 111 which is at the bottom of the groove 109. Therefore, the K value of the portion of the isolating layer 111 at the bottom of the groove 109 is still high. That is, the function of the air gap 113 to reduce the dielectric constant of the isolating layer 111 between the metal layers 101a is limited. Therefore, a crosstalk effect may arise between the metal layers 101a, which thereby affects the stability of the semiconductor device's performance.

It is further found that, if the interlayer dielectric layer is etched to make the groove extend the interlayer dielectric layer, the air gap formed subsequently may locate near to the bottom of the groove. Therefore, the K value of the isolating layer between the adjacent metal layers may be further reduced, which thereby alleviate a crosstalk effect between the adjacent metal layers.

However, the interlayer dielectric layer includes a dielectric material different from the metal film. Generally, after the metal layer (namely, metal pattern) is obtained by etching the metal film, the semiconductor device needs to be transferred to another etching device to etch the interlayer dielectric layer, during which the sidewall of the metal layer is exposed to air and is susceptible to corrosion of oxygen or water in the air. Further, the sidewall of the metal layer may be damaged when etching a substrate, which thereby affects the performance of the semiconductor device.

Embodiments of the present disclosure provide a method for forming a semiconductor device, which makes the air gap more close to the bottom of the groove. Therefore, a high-quality metal layer may be obtained, and the semiconductor device may have a stable performance.

In order to clarify the objects, characteristics and advantages of the disclosure, the embodiments of the present disclosure will be described in detail in conjunction with the accompanying drawings.

Referring to FIG. 4, a method for forming a semiconductor device according to one embodiment of the present disclosure may include:

S201, provide an interlayer dielectric layer, a metal layer formed on the interlayer dielectric layer, an etch stop layer formed on the metal layer, and a first opening extending through the etch stop layer and the metal layer, wherein the interlayer dielectric layer is exposed from the first opening;

S203, form a protecting layer on the sidewall of the first opening to cover the metal layer;

S205, after forming the protecting layer, form a second opening by etching a portion of the interlayer dielectric layer; and

S207, form an isolating layer by filling up the second opening, wherein the isolating layer includes an air gap.

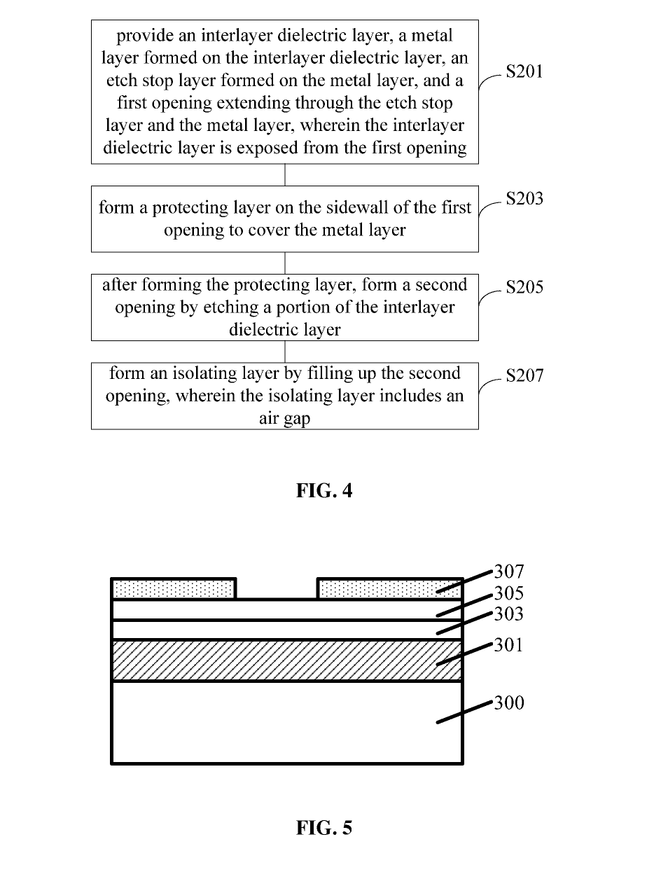

Specifically, refer to FIG. 5 to FIG. 10, which schematically illustrate cross-sectional views of intermediate structures of a method for forming a semiconductor device according to one embodiment of the present disclosure.

Referring to FIG. 5, provide an interlayer dielectric layer 300, a metal film 301 covering the interlayer dielectric layer 300, a first etch stop film 303 covering the metal film 301, and a second etch stop film 305 covering the first etch stop film 303, and a mask layer 307 formed on the second etch stop film 305. A first opening is defined by the mask layer 307.

The interlayer dielectric layer 300 is adapted to isolate metal layers and devices located at the bottom of the interlayer dielectric layer 300. The interlayer dielectric layer 300 may include a dielectric material, such as silicon oxide or silicon oxynitride etc. The interlayer dielectric layer 300 may be formed by deposition, such as Chemical Vapor Deposition (CVD). In the embodiment, the interlayer dielectric layer 300 includes silicon oxide and is formed by CVD.

The metal film 301 serves as an interconnecting wire or a conductive plug, which may be formed by Physical Vapor Deposition (PVD). The metal film 301 may have a thickness ranging from about 4000 Å to about 8000 Å. In the embodiment, the metal film 301 includes aluminum and serves as an interconnecting wire, which has a thickness of 4000 Å.

In order to prevent a metal layer which is formed subsequently from being damaged in an etch process, an etch stop film is required to be formed on the surface of the metal film 301. The etch stop film may have a single-layer or a multi-layer stack structure, which may be used to form an etch stop layer to protect the metal layer from being damaged.

In the embodiment, the etch stop film has a double-layer stack structure, which includes the first etch stop film 303 covering the metal film 301 and the second etch stop film 305 covering the first etch stop film 303. The first etch stop film 303 is adapted to protect the metal layer from being damaged in subsequent etch process. The first etch stop film 303 may be used as a mask when etching the interlayer dielectric layer 300. Therefore, there is a high etch selectivity between the first etch stop film 303 and the interlayer dielectric layer 300. In the embodiment, the first etch stop film 303 includes titanium nitride. The second etch stop film 305 includes silicon oxynitride.

It should be noted that the etch stop film may be a single layer, which may include silicon nitride, titanium nitride, silicon oxynitride, and so on. In order to ensure that the single-layer etch stop film can effectively protect the metal layer in subsequent etching process, the thickness of the single-layer etch stop film is set according to the following etching process. That is, after the second opening is formed after over-etching, a portion of the etch stop film having a certain thickness is still remained on the surface of the metal layer, which will not be described in detail herein.

The mask layer 307 locates on the surface of the second etch stop film 305, and is adapted to define the location of the first opening. In the embodiment, the mask layer 307 includes photoresist, which is formed by exposure and development, and will not be described in detail herein.

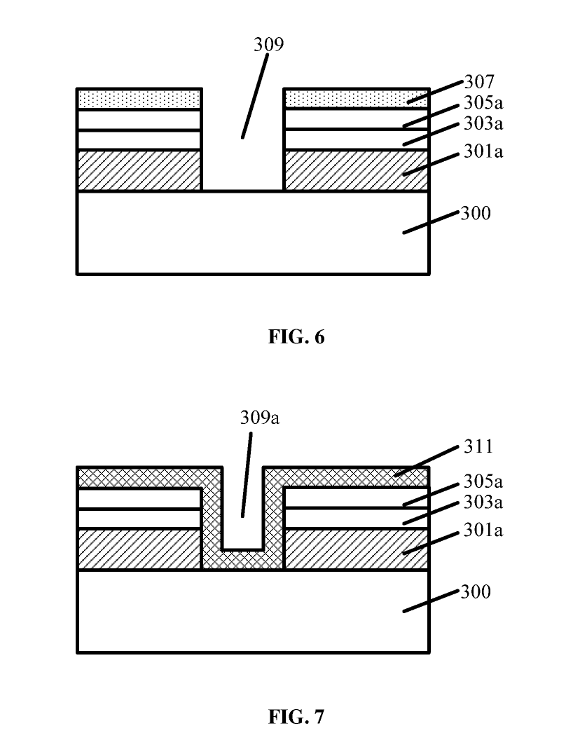

Referring to FIG. 6, form a second etch stop layer 305a, a first etch stop layer 303a, a metal layer 301a and a first opening 309 by successively removing the second etch stop film 305 (shown in FIG. 5), the first etch stop film 303 (shown in FIG. 5) and the metal film 301 (shown in FIG. 5) using the mask layer 307 as a mask. The first opening 309 extends through the second etch stop layer 305a, the first etch stop layer 303a and the metal layer 301a. The interlayer dielectric layer 300 is exposed from the first opening 309.

An etch process may be used to remove the second etch stop film 305, the first etch stop film 303 and the metal film 301. The second etch stop layer 305a is obtained after etching the second etch stop film 305. The first etch stop layer 303a is obtained after etching the first etch stop film 303. The metal layer 301a is obtained after etching the metal film 301.

The second etch stop layer 305a and the first etch stop layer 303a are adapted to prevent the metal layer 301a from being damaged in subsequent etch process for forming a second opening. In the embodiment, an anisotropic dry etch process is used to etch the second etch stop layer 305a and the first etch stop layer 303a.

The metal layer 301a serves as a conductive plug or an interconnecting wire. An etch process, such as an anisotropic dry etch process or an anisotropic wet etch process, may be used to form the metal layer 301a. In the embodiment, an anisotropic dry etch process is used to form the metal layer 301a.

A portion of the interlayer dielectric layer 300 is exposed from the first opening 309. The depth-to-width ratio of the first opening 309 is equal to or greater than 1:1 or close to 1:1. The first opening 309 has a width (a dimension along a direction parallel to the surface of the interlayer dielectric layer 300) ranging from about 4000 Å to about 8000 Å, and a depth (a dimension along a direction perpendicular to the surface of the interlayer dielectric layer 300) ranging from about 4000 Å to about 10000 Å.

Referring to FIG. 7, remove the mask layer 307 (shown in FIG. 6) and form a protecting film 311 covering the second etch stop layer 305a, the first etch stop layer 303a, and the bottom and the sidewall of the first opening 309.

The protecting film 311 is used to form a protecting layer subsequently, so as to protect the surface of the metal layer 301a exposed from the sidewall of the first opening 309, which may improve performance of the semiconductor device to be formed subsequently. In the embodiment, the protecting film 311 includes silicon oxide which is formed by deposition of tetraethoxysilane (TEOS). The deposition process for forming silicon oxide is known to those skilled in the art, and will not be described in detail herein.

Considering that the protecting film 311 is too thin to protect the surface of the metal layer 301a exposed from the sidewall of the first opening 309, the protecting film 311 has a thickness ranging from about 100 Å to about 500 Å. After the protecting film 311 is formed, the first opening 309 turns to be the first opening 309a shown in FIG. 7.

It should be noted that the protecting film 311 may be formed after the second etch stop layer 305a is removed, which will not be described in detail herein. The protecting film 311 may include a low-k dielectric material, such as silicon nitride or silicon oxynitride, etc.

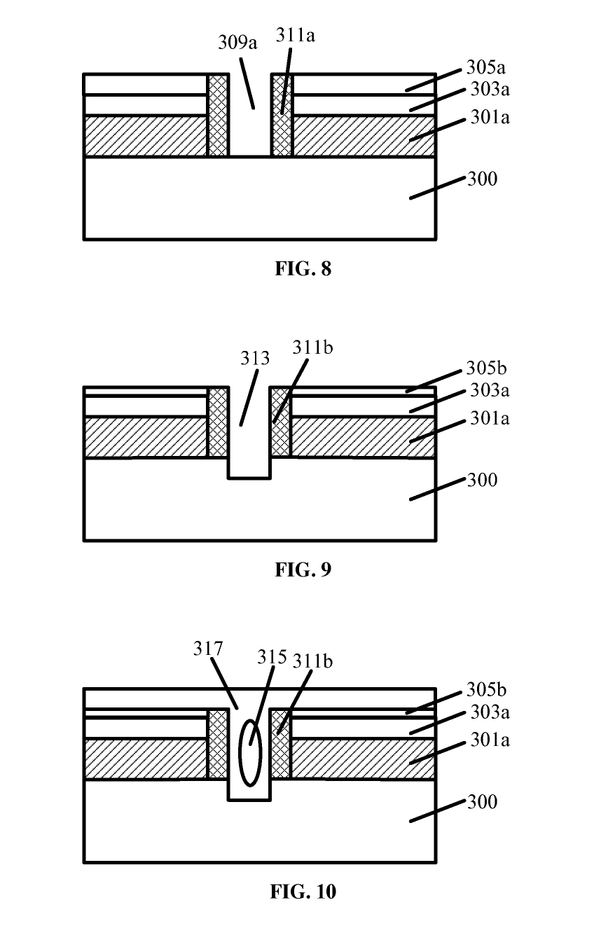

Referring to FIG. 8, remove the protecting film 311 on the surface of the second etch stop layer 305a and at the bottom of the first opening 309a, so as to form a protecting layer 311a on the surface of the first opening 309a, which covers the metal layer 301a.

An anisotropic dry etch process may be used to remove the protecting film 311 on the surface of the second etch stop layer 305a and at the bottom of the first opening 309a. The protecting film on the surface of the first etch stop layer 303a and the protecting film at the bottom of the first opening 309a may be formed in a same process, which thereby may save process steps.

The protecting layer 311a may effectively protect the surface of the metal layer 301a exposed from the sidewall of the first opening 309a. The protecting layer 311a defines a location and a size of a second opening. The protecting layer 311a may have a material and a thickness same with the protecting film 311. In the embodiment, the protecting layer 311a includes silicon oxide and has a thickness ranging from about 100 Å to about 500 Å.

It should be noted that, if the protecting film 311 is formed covering the first etch stop layer 303a, the protecting film 311 covering the first etch stop layer 303a and at the bottom of the first opening 309a needs to be removed, which will not be described in detail herein.

Referring to FIG. 9, after forming the protecting layer 311a, etch the interlayer dielectric layer 300 to form a second opening 313.

In order to alleviate a crosstalk effect between adjacent metal layers, the air gap to be formed locates more close to the bottom of the second opening 313. In the embodiment, after the protecting layer 311a is formed, it is required to etch the interlayer dielectric layer 300 to a certain thickness. An anisotropic dry etch process may be used to etch the interlayer dielectric layer 300.

The second opening 313 is used to form an isolating layer subsequently. The second opening 313 is etched using the protecting layer 311a and a second etch stop layer 305b as a mask. In order to prevent the metal layer 301a from being damaged in the etch process, after the interlayer dielectric layer 300 is etched to a certain thickness, the second etch stop layer 305b is still remained covering the first etch stop layer 303a. In the embodiment, a thickness ranging from about 2000 Å to about 3000 Å of the interlayer dielectric layer 300 is etched. That is, the second opening 313 has a depth about 2000 Å to about 3000 Å greater than that of the first opening.

In order to facilitate subsequent formation of an air gap 315, the second opening 313 has a depth-to-width ratio greater than 1.2.

It should be noted that, when etching the interlayer dielectric layer 300, a portion of the second etch stop layer 305a (shown in FIG. 8) may be etched as well. When the second opening 313 is formed, the remained second etch stop layer 305b covers the surface of the first etch stop layer 303a. In some embodiments, when etching the interlayer dielectric layer 300, the second etch stop layer 305a may be removed totally, even a portion of the first etch stop layer 303a may be removed. Just be sure that the surface of the metal layer 301a is not damaged after the second opening 313 is formed.

It should be noted that, the etch processes for removing the metal film 301 and the interlayer dielectric layer 300 are different and are performed using different equipments, since the metal film 301 and the interlayer dielectric layer 300 include different materials. Further, the interval between the etch processes for removing the metal film 301 and the etch processes for removing the interlayer dielectric layer 300 is very long, so the protecting layer 311a can effectively protect the metal layer 301a, which thereby improve the stability of the semiconductor device's performance.

Referring to FIG. 10, fill up the second opening 313 (shown in FIG. 9) to form an isolating layer 317, wherein the isolating layer 317 has an air gap 315 therein.

The isolating layer 317 is adapted to isolate adjacent metal layers 301a to avoid a crosstalk effect between the adjacent metal layers 301a. The isolating layer 317 includes a low-k material which has a poor filling property and is easy to form an air gap, e.g., silicon oxide. The isolating layer 317 may be formed by CVD. In the embodiment, the isolating layer 317 fills up the second opening 313 and covers the surface of the second etch stop layer 305b. The isolating layer 317 covering the surface of the second etch stop layer 305b has a thickness ranging from about 8000 Å to about 10000 Å.

The air gap 315 is adapted to reduce the dielectric constant of the isolating layer 317 and reduce RC delay and parasitic capacitance between adjacent metal layers 301a, so as to effectively avoid a crosstalk effect between the adjacent metal layers 301a.

In the embodiment, it is easy to form the air gap 315 because the second opening has a large depth and the material of the isolating layer 317 has a poor filling property. Further, the air gap 315 locates more close to the bottom of the metal layer 301a since the bottom of the second opening 313 locates in the interlayer dielectric layer 300. It is found that, with the same process conditions, the air gap formed with the method provided in embodiments of the present disclosure locates lower about 100 nm to 150 nm than that formed with the conventional method, which is more close to the bottom of the metal layer 301a. As a result, the K value of the isolating layer 317 between the adjacent metal layers 301a is further reduced, which thereby effectively alleviates a crosstalk effect between the adjacent metal layers 301a.

After the processes described above, the semiconductor device provided in embodiments of the present disclosure is formed. Because the protecting layer is formed on the sidewall of the first opening to cover the metal layer, the metal layer would not be damaged no matter when the interlayer dielectric layer is etched to form the second opening. Further, because the second opening is deeper than the first opening, the air gap is formed more close to the bottom of the metal layer, such that the K value of the isolating layer between adjacent metal layers is further reduced, which thereby effectively alleviates a crosstalk effect between the adjacent metal layers, and improves the stability of the semiconductor device's performance.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

We claim:

1. A method for forming a semiconductor device, comprising:
providing an interlayer dielectric layer, a metal layer formed on the interlayer dielectric layer, an etch stop layer formed on the metal layer, and a first opening extending through the etch stop layer and the metal layer, wherein the interlayer dielectric layer is exposed from the first opening;
forming a protecting layer on a sidewall of the first opening to cover the metal layer;
after forming the protecting layer, forming a second opening by etching a portion of the interlayer dielectric layer; and
forming an isolating layer by filling up the second opening, wherein the isolating layer comprises an air gap.

2. The method according to claim 1, wherein the protecting layer comprises silicon oxide, silicon nitride or silicon oxynitride.

3. The method according to claim 1, wherein the protecting layer is formed by oxidation of tetraethoxysilane (TEOS).

4. The method according to claim 1, wherein the protecting layer has a thickness ranging from about 100 Å to about 500 Å.

5. The method according to claim 1, wherein the second opening has a depth-to-width ratio greater than 1.2.

6. The method according to claim 1, wherein the second opening is about 2000 Å to about 3000 Å deeper than the first opening.

7. The method according to claim 1, wherein the first opening has a depth-to-width ratio equal to or greater than 1:1, and a width ranging from about 4000 Åto about 8000 Å, and a depth ranging from about 4000 Å to about 10000 Å.

8. The method according to claim 1, wherein the isolating layer comprises silicon oxide.

9. The method according to claim 1, wherein the etch stop layer comprises silicon nitride or titanium nitride.

10. The method according to claim 1, wherein the etch stop layer has a single-layer structure or a multi-layer stack structure.
